(19) United States
(12) Patent Application Publication
(10) Pub. No.: US 2026/0297724 A1
(43) Pub. Date: Oct. 1, 2026

(54) MOLYBDENUM TARGET AND METHOD FOR PRODUCING THE SAME

(71) Applicant: ULVAC, INC., Kanagawa (JP)

(72) Inventors: Ryota NAKAMURA, Kanagawa (JP); Taku OKUBO, Kanagawa (JP); Taiga SAKAMOTO, Kanagawa (JP)

(21) Appl. No.: 19/478,212

(22) PCT Filed: May 14, 2024
(86) PCT No.: PCT/JP2024/017842

§ 371 Date: Oct. 23, 2025

(30) Foreign Application Priority Data
May 15, 2023 (JP) 2023-080476

(51) Int. Cl. C23C 14/34

(52) U.S. Cl. CPC C23C 14/3414

(57) ABSTRACT

A molybdenum target is provided in which pore generation, a cause of particle formation, is suppressed, and pore size and distribution are precisely controlled. The target is formed from a sintered body of molybdenum powder and has a relative density of 99% or higher, an oxygen content of 25 ppm or less, a carbon content of 30 ppm or less, a tungsten content of 10-100 ppm, and a molybdenum content (excluding oxygen, carbon, and tungsten) of 99.999 mass % or more. Within an observation field of 0.15 mm², the target contains 20 or fewer pores of 0.01 μm² to <0.2 μm², 5 or fewer pores of 0.2 μm² to <1.8 μm², and at most 1 pore of ≥1.8 μm². A production method for achieving these characteristics is also provided.

### TECHNICAL FIELD

The present invention relates to a molybdenum target formed of a sintered body of molybdenum powder, and to a method for producing the target.

### BACKGROUND ART

In recent years, tungsten is widely used as a wiring or electrode material in the production of semiconductor devices by virtue of its advantageous properties of heat resistance and low electrical resistance. Tungsten film is generally formed through sputtering. In a sputtering process for forming tungsten film, argon ions generated through plasma discharge are caused to collide with a tungsten target, to thereby beat tungsten atoms out of the surface of the target. As a result, tungsten atoms are deposited on a substrate disposed to oppositely face the target. In the above process, there has been known a serious problem that deposition of particles provided from the surface of the target on the substrate reduces the production yield. Thus, there is demand for a tungsten target which provides a highly limited number of particles and has minute and uniform crystal grains and a high relative density.

However, even if a high-purity tungsten film can be formed, the film would not satisfy future demand for further reduction in resistance. Therefore, a promising material replacing tungsten must be developed.

In this regard, molybdenum film attracts attention, since it could achieve satisfactorily low electrical resistance. However, there is also known a problem that molybdenum film often generates particles during sputtering, to thereby reduce the yield of product material.

To solve the above problems, there have been proposed a molybdenum sputtering target which can achieve effectively reduced particle generation during sputtering, and a method for producing the sputtering target. The proposed target has a molybdenum content of 99.99 mass % or more, a relative density of 98% or higher, and an average crystal grain size of 400 μm or less. The production method includes a step of preparing a molybdenum powder; a step of conducting hot-pressing of the molybdenum powder at 1,350° C. to 1,500° C. under application of a load; and a step of conducting hot isostatic pressing, at 1,300° C. to 1,850° C., of the compact obtained through the hot-pressing step (see Patent Document 1).

### PRIOR ART DOCUMENTS

### Patent Documents

Patent Document 1: Japanese Patent Application Laid-Open (kokai) No. 2022-125041

### SUMMARY OF THE INVENTION

### Problems to be Solved by the Invention

However, a study has revealed that generation of particles originating from such a molybdenum target cannot be sufficiently reduced, even when the technique disclosed in Patent Document 1 is employed.

Particularly, as the down-scaling of wiring and the like employing molybdenum progresses, particles generated from the molybdenum target considerably affect the yield of molybdenum film. Thus, demand has arisen for further suppression of particle generation.

Previously, the inventors investigated a main cause of particle generation during film formation through sputtering a molybdenum target. As a result, the inventors revealed that particle generation causing a drop in yield was not successfully suppressed, since unavoidable pores were present in the target which was produced through the aforementioned production method, although the relative density of the sintered body forming the target reached substantially 100%, and the size and distribution state of the pores were not regulated.

Therefore, enhancing the yield requires a molybdenum target which generates possibly few particles, and a method for producing the molybdenum target.

Under such circumstances, an object of the present invention is to provide a molybdenum target in which generation of pores (i.e., a cause of particle generation) is suppressed and the size and distribution state are regulated at high precision. Another object is to provide a method for producing the target.

### Means for Solving the Problems

In a first mode of the present invention to attain the aforementioned objects, there is provided a molybdenum target formed of a sintered body of a molybdenum powder, which target has a relative density of 99% or higher, an oxygen content of 25 ppm or less, a carbon content of 30 ppm or less, a tungsten content of 10 ppm to 100 ppm, and a molybdenum content, excluding the oxygen content, the carbon content, and the tungsten content, of 99.999 mass % or more; and in which, in an observation field of 0.15 mm², 20 or fewer pores having a size of 0.01 μm² or greater and smaller than 0.2 μm² are present; 5 or fewer pores having a size of 0.2 μm² or greater and smaller than 1.8 μm² are present; and 1 or fewer pore having a size of 1.8 μm² or grater is present.

A second mode of the present invention is a specific embodiment of the molybdenum target of the first mode, which has an average grain size d_{Ave}, calculated as a circle-equivalent diameter, of 20 μm to 100 μm, and a ratio (30/d_{Ave}) of the standard deviation 3σ of the grain sizes, calculated as circle-equivalent diameters, to the average grain size d_{Ave} of 1.2 or less.

A third mode of the present invention is a specific embodiment of the molybdenum target of the second mode, which has an average aspect ratio regarding grain size less than 1.2.

A fourth mode of the present invention is a specific embodiment of the molybdenum target of the first to third modes, which has an average Vickers hardness of 180 or less, and a ratio (3σ/H_{Ave}) of the standard deviation 3σ of Vickers hardness values to the average Vickers hardness H_{Ave} of 0.07 or less.

In a fifth mode of the present invention, there is provided a method for producing a molybdenum target, the method comprising using a molybdenum powder which has an average particle size D_{Ave} of 2.5 to 4.0 μm, the particle size being determined through a laser diffraction/scattering method, a median diameter D50 of 2.0 to 3.5, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less; hot-pressing the molybdenum powder at 1,400° C. to 1,500° C.; and subsequently, sintering the hot-pressed product at 1,500° C. to 1,600° C. through a hot isostatic pressing method.

A sixth mode of the present invention is a specific embodiment of the molybdenum target production method of the fifth mode, wherein the molybdenum powder has a tungsten content of 10 ppm to 100 ppm, and a molybdenum content, excluding an oxygen content, a carbon content, and the tungsten content, of 99.999 mass % or more.

A seventh mode of the present invention is a specific embodiment of the molybdenum target production method of the fifth or sixth mode, wherein the hot-pressing is conducted in high vacuum at a retention temperature of 1,400 to 1,500° C. for a retention time of 360 to 600 minutes.

### Effects of the Invention

According to the present invention, there can be realized a molybdenum target in which generation of pores (i.e., a cause of particle generation) is suppressed and the size and distribution state are regulated at high precision and a method for producing the target.

### BRIEF DESCRIPTION OF THE DRAWINGS

FIG. 1 A graph showing the relationship between the number of pores having a size of 0.01 to 0.2 μm² and the number of particles, the numbers determined in the Examples of the present invention and the Comparative Examples.

FIG. 2 A graph showing the relationship between the number of pores having a size of 0.2 to 1.8 μm² and the number of particles, the numbers determined in the Examples of the present invention and the Comparative Examples.

FIG. 3 A graph showing the relationship between the number of pores having a size of 1.8 μm² or more and the number of particles, the numbers determined in the Examples of the present invention and the Comparative Examples.

### MODES FOR CARRYING OUT THE INVENTION

The molybdenum target of the present invention, molybdenum has a purity (Mo content) of 5N (99.999 mass %) or higher, a relative density of 99% or higher, an oxygen content of 25 ppm or less, a carbon content of 30 ppm or less, and a tungsten content of 10 ppm to 100 ppm, and in which, in an observation field of 0.15 mm², 20 or fewer pores having a size of 0.01 μm² or greater and smaller than 0.2 μm² are present; 5 or fewer pores having a size of 0.2 μm² or greater and smaller than 1.8 μm² are present; and 1 or fewer pore having a size of 1.8 μm² or greater is present. Notably, “a molybdenum purity of 5N” means that the molybdenum content, excluding the oxygen content, the carbon content, and the tungsten content, is 99.999 mass % or more.

### (Purity)

For forming a molybdenum film having low specific resistivity, the impurity level of the molybdenum film must be controlled to be low. Thus, the purity of the molybdenum target is essentially enhanced. Specifically, a purity of 99.999 mass % (5N) or higher is required.

### (Gas Component)

Gas components such as carbon and oxygen present in a molybdenum target adversely affect the specific resistivity of a molybdenum film formed from the target. These gas components are incorporated into a molybdenum film during formation of the film. Thus, as the gas component content increases, the specific resistivity of the molybdenum film tends to increase. Preferably, the carbon content of the molybdenum target is 30 ppm by mass or less, and the oxygen content is 25 ppm by mass or less.

### (Tungsten Content)

The molybdenum target of the present invention has a tungsten content of 10 ppm to 100 ppm, preferably 20 ppm to 50 ppm.

Controlling the tungsten content to satisfy the above conditions is based on the following reasons.

Normally, the tungsten content is reduced to an unavoidable impurity level. However, in the present invention, the tungsten content is set to fall within a specific range. Generally, when the tungsten content is excessively small, undesired grain growth easily occurs during sintering, whereby the crystal grain size increases, and large pores are readily provided. In contrast, when the tungsten content is excessively high, sintering performance is impaired, and difficulty is encountered in achieving high density.

### (Crystal Grain Size)

The molybdenum target of the present invention has an average crystal grain size d_{Ave}, calculated as a circle-equivalent diameter, of 20 μm to 100 μm.

Controlling the mean value of the crystal grain sizes (i.e., average grain size) to fall within the above range is based on the following reasons.

As the average grain size of the molybdenum target decreases, variation in the amount of erosion attributed to the difference in orientation of the crystal grains present in the surface of the target can be reduced. As a result, occurrence of anomalous discharge due to the roughness of the surface can be reduced, to thereby suppress generation of particles during film formation.

In contrast, when the average grain size excessively decreases, the film formation rate excessively decreases, causing a drop in productivity.

Meanwhile, the ratio (3σ/d_{Ave}) of the standard deviation 3σ of the grain sizes, calculated as circle-equivalent diameters, to the average grain size d_{Ave} is 1.2 or less. The ratio is calculated by dividing the standard deviation 3σ by the average grain size.

Also, the aspect ratio regarding grain size is less than 1.2. The aspect ratio is defined as a ratio of the major axis to the minor axis of a crystal grain image provided for determining a “grain size calculated as a circle-equivalent diameter” and is determined by use of image analysis software “Image-j.”

The reason why the ratio (30/d_{Ave}) of the standard deviation 3σ of the grain sizes to the average grain size d_{Ave} is preferably 1.2 or less is as follow.

Variation in crystal grain size correlates with the number of pores and the pore size. The smaller the variation in crystal grain size, the fewer the pores in the target and the smaller the pore size. Thus, when the ratio (30/d_{Ave}) falls within the above range, generation of particles can be suppressed during film formation.

In addition, the aspect ratio regarding grain size is preferably less than 1.2, since a consistent film formation rate that does not adversely affect production can be achieved, and replacement of the target does not readily cause variation in film formation rate.

### (Relative Density)

The relative density of the molybdenum target is preferably controlled to 99% or higher. When the relative density of the target is 99% or higher, the amount of gas components present in the target decreases, whereby a rise in specific resistivity of a film can be suppressed in formation of the film. Also, the higher the relative density of the target, the smaller the number of pores. As a result, occurrence of anomalous discharge due to the roughness of the surface can be reduced, to thereby suppress generation of particles during film formation.

### (Vickers Hardness)

The average Vickers hardness of the molybdenum target is preferably 160 to 180, more preferably 165 to 175.

The reason why an average Vickers hardness satisfying the above conditions is preferred is as follows.

The average Vickers hardness correlates with the number of pores in the target and the pore size. The higher the average Vickers hardness, the smaller the number of pores in the target, and the smaller the pore size. As a result, generation of particles can be suppressed during film formation.

In contrast, when the average Vickers hardness is considerably great, highly conceivably, the target has not been received a heat treatment under appropriate conditions, failing to remove strain in the molybdenum target. In this case, cracking may occur from the internal strain through thermal stress during processing of the target or film formation through sputtering.

Also, the ratio (3/H_{Ave}) of the standard deviation 3σ of Vickers hardness values to the average Vickers hardness H_{Ave} is preferably 0.07 or less. The ratio is calculated by dividing the standard deviation 3σ by the average Vickers hardness.

The reason why the ratio (30/H_{Ave}) of the triple value of the standard deviation (3σ) of Vickers hardness to the average Vickers hardness preferably falls within the above range is as follows.

Variation in Vickers hardness correlates with the number of pores and the pore size. The smaller the variation in Vickers hardness, the fewer the pores in the target and the smaller the pore size. Thus, generation of particles can be suppressed during film formation.

### (Pores)

In the molybdenum target of the present invention, in an observation field of 0.15 mm², 20 or fewer pores having a size of 0.01 μm² or greater and smaller than 0.2 μm² are present; 5 or fewer pores having a size of 0.2 μm² or greater and smaller than 1.8 μm² are present; and 1 or fewer pore having a size of 1.8 μm² or greater is present.

The reason for controlling the pore size and the number of pores in the present invention to satisfy the aforementioned conditions is as follows.

By regulating the pore size and the number of pores, an electric field can be focused on the pores, whereby generation of particles, which would otherwise be caused by local dissolution and scattering, can be suppressed. As a result, an enhanced yield can be achieved. In addition, suppression of particle generation is continuously maintained to the life end of the target, to thereby achieve consistent production.

Hitherto, there has been realized no molybdenum target which has only a limited number of such coarse pores and in which localization of pores to the plane and thickness directions of the molybdenum target is suppressed. However, the problem can be solved by virtue of the aforementioned characteristics including a relative density, a hardness, and a crystal grain size. Also, the molybdenum target of the present invention, which has only a limited number of such coarse pores and in which localization of pores to the plane and thickness directions of the molybdenum target is suppressed, can be produced through the production method mentioned below.

As described hereinabove, the molybdenum target of the present invention has only a few pores and a small pore size. Thus, by employing the molybdenum target, particle generation can be considerably reduced, to thereby consistently form a high-quality molybdenum film.

Hereinafter, there will next be described a method of producing a molybdenum target according to one embodiment of the production of the molybdenum target of the present invention.

The molybdenum target of the present invention can be produced by using a molybdenum powder which has an average particle size D_{Ave} Of 2.5 to 4.0 μm, the particle size being determined through a laser diffraction/scattering method, and a median diameter D50 of 2.0 to 3.5; hot-pressing the molybdenum powder at 1,400° C. to 1,500° C. (HP step); and subsequently, sintering the hot-pressed product at 1,500° C. to 1,600° C. through a hot isostatic pressing method (HIP step).

A first key point of the sputtering target production method of the present invention is to use a molybdenum powder having an average particle size D_{Ave}, as determined through a laser diffraction/scattering method, of 2.5 to 4.0 μm, preferably 2.8 to 3.7 μm, and a median diameter D50 of 2.0 to 3.5, preferably 2.2 to 3.3 μm.

A second key point of the sputtering target production method of the present invention is to use a molybdenum powder having a ratio (D90/D_{Ave}) of a median diameter D90 to the average particle size D_{Ave} of 1.7 or less, preferably 1.5 or less.

Further, a third key point of the sputtering target production method of the present invention is to use a molybdenum powder having a ratio (D95/D_{Ave}) of a median diameter D95 to the average particle size D_{Ave} of 2.0 or less, preferably 1.8 or less.

Thus, according to the present invention, a molybdenum target which has only a few pores and a considerably small size can be provided by use of a molybdenum powder having a particle size falling within a specific range and a considerably narrow particle size distribution profile (i.e., a small variation in particle size from the average particle size). In the present invention, such a narrow particle size distribution feature is defined by a ratio of a median diameter D90 to the average particle size D_{Ave}, as determined through the laser diffraction/scattering method, or a ratio of a median diameter D95 to the average particle size D_{Ave}, as determined through the laser diffraction/scattering method, wherein the ratio is equal to or smaller than a predetermined value. Notably, a powder having a wide particle size distribution profile falling outside the range fails to exert the effects of the present invention.

When the average particle size of the powder is excessively large, a sintered body having a density of interest cannot be yielded. When the average particle size of the powder is small, the density of the sintered body steeply rises during hot-pressing (HP), to thereby trap oxides. Thus, the average particle size of the powder must be controlled to fall within a specific range.

The molybdenum powder employed in the present invention has a tungsten content of 10 ppm to 100 ppm and a molybdenum content, excluding the oxygen content, the carbon content, and the tungsten content, of 99.999 mass % or more.

Notably, the oxygen content of the powder is a key factor to control the oxygen content of the molybdenum target. Thus, the oxygen content of the raw material powder is preferably controlled to, for example, 3,000 ppm by mass or less. When the oxygen content is higher, the amount of sublimated oxide increases, thereby possibly damaging a hot-press apparatus.

The sputtering target of the present invention can be produced by hot-pressing the aforementioned molybdenum powder at 1,400° C. to 1,500° C. and, subsequently, sintering the hot-pressed product at 1,500° C. to 1,600° C. through a hot isostatic pressing method.

By conducting vacuum hot-pressing in a high vacuum state, degassing and sintering are promoted, whereby a high-density sintered body can be yielded, while the oxygen content of the molybdenum target is reduced. When the oxygen content of the molybdenum power is high, the amount of oxide in the molybdenum target increases, resulting in an increase in occurrence of particle generation. In addition, a thick surface oxide film impedes sintering, thereby failing to yield a high-density sintered body.

As used herein, the term “high vacuum” refers to a pressure of 1×10⁻² Pa or lower, preferably 1×10⁻³ Pa or lower, more preferably 1×10⁻⁴ Pa or lower.

Meanwhile, as described above, gas components such as carbon and oxygen present in the molybdenum target adversely affects the specific resistivity of the molybdenum film. Therefore, the carbon content of the molybdenum target is preferably 30 ppm by mass or less, and the oxygen content thereof is preferably 25 ppm by mass or less.

As mentioned above, the oxygen content can be achieved through vacuum hot-pressing.

However, an increase in carbon content is caused by diffusion of carbon originating from a graphite member forming a hot-press apparatus to the molybdenum sintered body during hot-pressing. Therefore, the hot-pressing temperature is preferably controlled to as low a level as possible. When the temperature is 1,500° C., a carbon content of 30 ppm by mass or less, suitably 20 ppm by mass or less, can be consistently achieved.

In the HP step, a sintered body having a relative density of 95% or higher is yielded. For producing a sintered body having such a property, the HP temperature is preferably 1,400° C. to 1,500° C. When the HP temperature is excessively low, the density of the sintered body cannot rise to such a level that an HIP treatment can be performed. When the HP temperature is excessively high, undesired rapid grain growth occurs to locally provide coarse pores. Both cases are not preferred. When the pressure of HP is too low, the density of the sintered body cannot rise to such a level that an HIP treatment can be performed. When the pressure of HP is excessively high, wear of the HP apparatus is aggravated. The pressure of HP treatment is, for example, 39.2 MPa (400 kg/cm²) to 44.1 MPa (450 kg/cm²). The HP retention time in the step is 360 minutes to 600 minutes. When the HP retention time is too short, the density of the sintered body cannot rise to such a level that an HIP treatment can be performed. When the HP retention time is excessively long, productivity decreases. In the present invention, essential points are to control the particle size of the powder and the particle size distribution, the HP temperature to 1,400° C. to 1,500° C., and the HP retention time to 360 minutes to 600 minutes. By virtue of such controlling, coarsening the pores in the sintered body can be suppressed, and minute pores can be uniformly dispersed in the sintered body.

The sintered body which has undergone the HP treatment is subjected to a hot isostatic pressing (HIP) method, for reducing the number of pores in the sintered body to achieve high density.

The HIP temperature is 1,500° C. to 1,600° C. When the HIP temperature is lower than 1,500° C., corresponding to a low treatment temperature, difficulty is encountered in achieving a relative density of 99% or higher within a treatment time suited for mass-production. Particularly, since a molybdenum powder having a tungsten content falling within a specific range is used in the present invention, a sintered body having a relative density of 99% or higher fails to be formed at a lower temperature of 1,500° C. When the HIP temperature exceeds 1,600° C., corresponding to a high treatment temperature, undesired rapid coarsening of crystal grains occurs to locally provide coarse pores, which is not preferred. No particular limitation is imposed on the HIP pressure, and the pressure is, for example, 100 to 200 MPa, and in the present embodiment, 176.4 MPa (1,800 kg/cm²).

According to the production method described above, a molybdenum target having characteristics of the present invention can be yielded. In particular, the number of pores present in the molybdenum target and the size of the pores can be reduced, to thereby suppress localization of the pores. Thus, by use of the sputtering target of the present embodiment, occurrence of particle generation during film formation can be reduced, whereby a high-quality molybdenum film can be consistently formed.

The presence of pores in the sputtering target strongly correlates with the particle size and its distribution of the raw material powder; the relative density of the sintered body; the crystal grain size and its distribution of the target; and the hardness and its distribution of the target. Thus, as the particle size of the raw material powder is smaller, and the particle size distribution is narrower, or as the relative density of the sintered body is higher, and variations in crystal grain size and hardness are smaller, generation of pores is considerably suppressed, and the pore size is minimized.

However, even if the crystal grain size is minute, when variation in crystal grain size is large, provision of coarse pores cannot be suppressed. The inventors have found the followings. Specifically, in the present invention, the particle size and its distribution of the raw material powder, hot-pressing conditions, and hot isostatic pressing conditions are optimized, whereby the relative density of the sintered body is enhanced, and variations in crystal grain size and hardness are suppressed. As a result, there can be produced the molybdenum target of the present invention, which has very few coarse pores and in which localization of pores is not substantially observed.

Accordingly, in the molybdenum target production method of the present embodiment, the raw material powder is hot-pressed at 1,400° C. to 1,500° C., and the hot-pressed product is then sintered at 1,500° C. to 1,600° C. through a hot isostatic pressing method.

According to the aforementioned molybdenum target production method, a sputtering target having a small pore size and only a few pores can be yielded. For example, the molybdenum target which can be consistently produced through the aforementioned production method exhibits in an observation field of 0.15 mm², 20 or fewer pores having a size of 0.01 μm² or greater and smaller than 0.2 μm²; 5 or fewer pores having a size of 0.2 μm² or greater and smaller than 1.8 μm²; and 1 or fewer pore having a size of 1.8 μm² or greater.

According to the molybdenum target production method of the present invention, a molybdenum target having the following properties can be effectively and consistently yielded. Specifically, the molybdenum target has a relative density of 99% or higher, a Vickers hardness of 180 or less, a ratio (3σ/H_{Ave}) of the standard deviation 3σ of Vickers hardness values to the average Vickers hardness H_{Ave} of 0.07 or less, an average grain size of 20 μm to 100 μm, and a ratio (3σ/D_{Ave}) of the standard deviation 3σ of the average grain sizes to the average grain size D_{Ave} of 1.2 or less.

Thus, according to the present invention, there can be produced a molybdenum target having only a few pores and a small pore size. By use of the molybdenum target, the amount of generated particles can be considerably reduced, whereby a high-quality molybdenum film can be consistently formed.

The thus-formed sintered body is processed in a processing step to a target shape of interest. No particular limitation is imposed on the processing method, and mechanical processing such as grinding or cutting is typically employed. The size and shape of the processed product are determined in response to the specification of the target. For example, targets of a circular shape, a rectangular shape, etc. are provided. By joining the processed sintered body to a backing plate, a sputtering cathode is provided.

### EXAMPLES

The present invention will next be described in detail with reference to the Examples and the Comparative Examples.

The average particle size and its distribution of molybdenum powder was determined by means of a particle size distribution meter (“LS13320,” product of MicrotracBEL Corp.).

### Examples 1 to 4

Molybdenum powders shown in Table 1 were used. These powder each had a tungsten content of 10 ppm to 100 ppm, molybdenum content (excluding tungsten and gas components) of 99.999 mass % or more (purity: 5N), an average particle size D_{Ave}, as determined through a laser diffraction/scattering method, of 2.5 to 4.0 μm, a median diameter D50 of 2.0 to 3.5, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less. Each powder was hot-pressed at 1,400° C. to 1,500° C. (as shown in Table 1), and then subjected to HIP at 1,500° C. to 1,600° C. (as shown in Table 1), to thereby yield a molybdenum sintered body. The thus-obtained molybdenum sintered body was grounded by means of a lathe, to thereby form a target having a shape of interest (diameter: 440 mm, thickness: 6 mm).

### Comparative Example 1

As shown in Table 1, there was used a molybdenum powder having an average particle size D_{Ave}, as determined through a laser diffraction/scattering method, less than 2.5 μm, a median diameter D50 less than 2.0 μm, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less. The powder was hot-pressed at a temperature shown in Table 1), to thereby yield a molybdenum sintered body. Conceivably, since the molybdenum powder had a too small particle size, the density of the sintered body steeply increased. As a result, a large amount of oxide was trapped.

### Comparative Example 2

As shown in Table 1, there was used a molybdenum powder having an average particle size D_{Ave}, as determined through a laser diffraction/scattering method, of 2.5 to 4.0 μm, a median diameter D50 of 2.0 to 3.5, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less. The powder was hot-pressed at a temperature shown in Table 1), to thereby yield a molybdenum sintered body. Since no HIP was conducted, the obtained sintered body failed to have a sufficient density.

### Comparative Examples 3 to 8

Molybdenum powders shown in Table 1 were used. These powder each had an average particle size D_{Ave}, as determined through a laser diffraction/scattering method, less than 2.5 μm, a median diameter D50 less than 2.0 μm, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less. Each powder was hot-pressed at a temperature shown in Table 1, and then subjected to HIP, to thereby yield a molybdenum sintered body. The thus-obtained molybdenum sintered body was grounded by means of a lathe, to thereby form a target having a shape of interest (diameter: 440 mm, thickness: 6 mm).

### Comparative Example 9

As shown in Table 1, there was used a molybdenum powder having an average particle size D_{Ave}, as determined through a laser diffraction/scattering method, of 2.5 to 4.0 μm, a median diameter D50 of 2.0 to 3.5 μm, a ratio (D90/D_{Ave}) Of a median diameter D90 to the average particle size D_{Ave} of 1.7 or more, and a ratio (D95/D_{Ave}) of a median diameter D95 to the average particle size D_{Ave} of 2.0 or more. The powder was hot-pressed at a temperature shown in Table 1, and then subjected to HIP, to thereby yield a molybdenum sintered body. The thus-obtained molybdenum sintered body was grounded by means of a lathe, to thereby form a target having a shape of interest (diameter: 440 mm, thickness: 6 mm).

### Comparative Example 10

As shown in Table 1, there was used a molybdenum powder having an average particle size D_{Ave}, as determined through a laser diffraction/scattering method, more than 4.0 μm, a median diameter D50 of 2.0 to 3.5 μm, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or more. The powder was hot-pressed at a temperature shown in Table 1, and then subjected to HIP, to thereby yield a molybdenum sintered body. The thus-obtained molybdenum sintered body was grounded by means of a lathe, to thereby form a target having a shape of interest (diameter: 440 mm, thickness: 6 mm).

### Comparative Examples 11 to 13

Molybdenum powders shown in Table 1 were used. These powder each had an average particle size D_{Ave}, as determined through a laser diffraction/scattering method, more than 4.0 μm, a median diameter D50 more than 3.5 μm, a ratio (D90/D_{Ave}) of a median diameter D90 to the average particle size D_{Ave} of 1.7 or more, and a ratio (D95/D_{Ave}) of a median diameter D95 to the average particle size D_{Ave} of 2.0 or more. Each powder was hot-pressed at a temperature shown in Table 1, and then subjected to HIP, to thereby yield a molybdenum sintered body. The thus-obtained molybdenum sintered body was grounded by means of a lathe, to thereby form a target having a shape of interest (diameter: 440 mm, thickness: 6 mm).

### Examples and Comparative Examples

The thus-obtained targets were subjected to measurements in terms of relative density, Vickers hardness, crystal grain size, tungsten content, oxygen content, carbon content, and pores, through the following procedures. Tables 2 and 3 show the results.

### (Relative Density)

From each of the obtained molybdenum targets, a sample (10×10×6 mmt) was collected at the center, an edge, and a middle point of a line between the center and the edge. A cross-section of each sample was polished and etched. Subsequently, the specific gravity of the sample was calculated through the Archimedes' principle. The relative density was calculated with a theoretical density of molybdenum (10.23 g/cm³). The measurements of relative density of the samples were summed, and the sum was divided by the number of samples, to thereby determine the relative density of a molybdenum target in the present invention.

### (Vickers Hardness)

From each of the obtained molybdenum targets, a sample (10×10×6 mmt) was collected at the center, an edge, and a middle point of a line between the center and the edge. A cross-section of each sample was polished. Then, the hardness of the sample was measured by means of a Vickers hardness meter (“HM-200,” product of Mitutoyo Corporation) at a load of 1 kg for a loading time of 15 seconds. The measurement was conducted thrice at the three points along the depth direction of the target with intervals of 1 mm. The obtained measurements were averaged. The averaged values of the samples were summed, and the sum was divided by the number of samples, to thereby determine the hardness of a molybdenum target in the present invention. Further, the standard deviation of the hardness values of the molybdenum target was determined by summing up the standard deviations of the samples, and dividing the sum by the number of samples. Thus, the standard deviation of the hardness of the present invention was determined.

### (Crystal Grain Size)

From each of the obtained molybdenum targets, a sample (10×10×6 mmt) was collected at the center, an edge, and a middle point of a line between the center and the edge. A cross-section of each sample was polished and etched. Subsequently, images of the target were taken along the depth direction of the target with intervals of 1 mm, by means of an optical microscope (“Digital Microscope VHX-6000,” product of Keyence Corporation). The images were analyzed by image analysis software “Image-j”, to thereby determine circle-equivalent diameters, and the diameters were averaged. The averages values of the test pieces were summed, and the sum was divided by the number of the samples, to thereby determine the average grain size of a molybdenum target in the present invention. Further, the standard deviation of the crystal grain size values of the molybdenum target was determined by summing up the standard deviations of the samples, and dividing the sum by the number of samples. Thus, the standard deviation of the crystal grain size of the present invention was determined.

### (Oxygen Content)

In the processing of a molybdenum sintered body into the target, an analytical sample was collected, and the oxygen content of the compact was determined. The oxygen content analysis was performed by means of an analyzer (“TC-600,” product of LECO).

### (Carbon Content)

In the processing of a molybdenum sintered body into the target, an analytical sample was collected, and the carbon content of the sintered body was determined. The carbon content analysis was performed by means of an analyzer (“EMIA-320V,” product of Horiba Ltd.).

### (Pores)

From each of the obtained sputtering targets, a sample (10×10×6 mmt) was collected at the center, an edge, and a middle point of a line between the center and the edge. A cross-section of each sample was polished. Subsequently, two SEM images of the target were taken along the depth direction of the target with intervals of 1 mm, by means of an electron microscope (“TM4000Plus,” product of Hitachi High-Tech Corporation). The SEM images were analyzed by image analysis software “Image-j”, to thereby determine pore areas, and the pore size and the number of pores of each sample were calculated. The pore sizes and the numbers of pores of the analyzed samples were summed, and the sum was divided by the number of the samples, to thereby determine the pore size and the number of pores of a molybdenum target in the present invention.

By use of the targets produced in the Examples and the Comparative Examples, film formation was performed through the following procedure. Specific resistivity of each film was measured, and generation of particles was assessed, in the following manner.

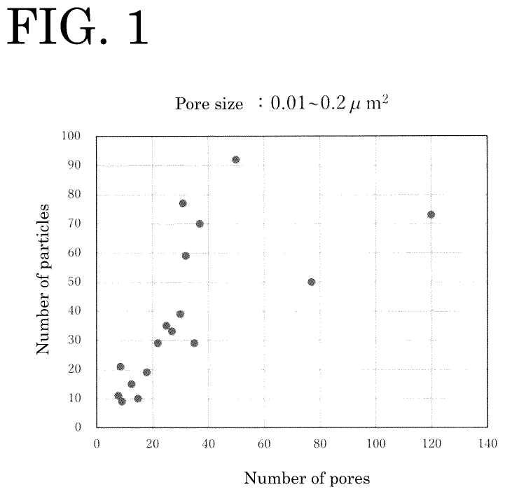

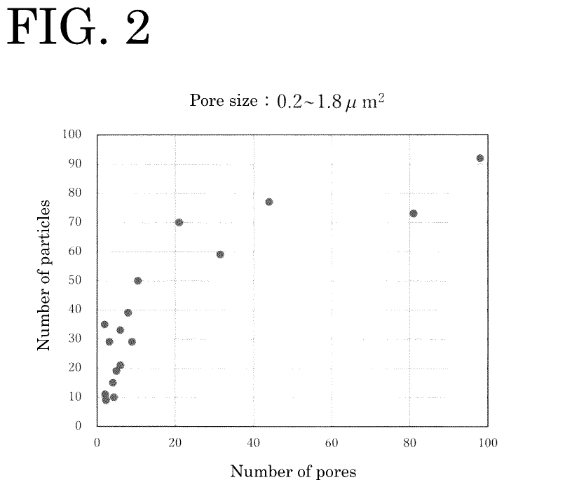

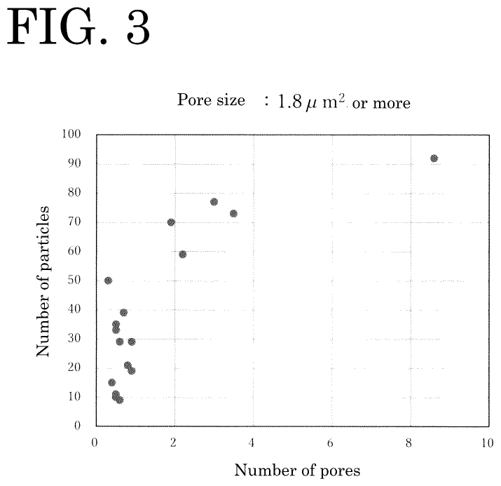

Table 3 shows the results of Examples 1 to 4 and Comparative Examples 1 to 13. FIGS. 1 to 3 each show the relationship between the number of pores having a particular size and the number of particles. In Table 3, a specific resistivity of 11 μΩ·cm or lower is denoted by “O,” and that in excess of 11 μΩ·cm is denoted by “X.” When the specific resistivity is 11 μΩ·cm or lower, a film for providing a low-resistance LSI wiring can be formed, leading to achieving a device of low power consumption.

Also, “film thickness distribution” was assessed with “O” in the case of 2% or less and with “X” in the case of >2%. When the film thickness distribution is 2% or less, relevant devices can be consistently produced with a small variation in performance/quality.

### (Specific Resistivity Measurement)

Each of the obtained molybdenum targets was bounded to a backing plate made of an aluminum alloy by the mediation of an In-based brazing material, to thereby fabricate a sputtering cathode. The sputtering cathode was attached to a sputtering apparatus (“ENTRON (registered a trademark),” product of ULVAC, Inc.), whereby a molybdenum thin film (thickness: 10 nm) was formed on a semiconductor wafer (diameter: 300 mm). Sputtering conditions; target pressure: 1×10⁻⁵ Pa, discharge mode: DC, power: 4 kW, gas source: Ar, gas flow: 150 sccm, film formation temperature: 200° C., sputtering time: 5 seconds, and target-wafer distance: 60 mm.

The thickness of a molybdenum thin film on the wafer was measured at nine points by means of “S-MAT2300” (product of TECHNORAYS). In a similar manner, sheet resistivity was measured by means of “OmniMap RS100” (product of KLA-Tencor). Thus, the specific resistivity (μΩ·cm) of the thin film was calculated. The specific resistivity measurements were averaged, to thereby provide the specific resistivity of a molybdenum thin film.

### (Counting of Particles)

The surface of the molybdenum thin film (thickness: 10 nm) which had undergone specific resistivity measurement was inspected by means of a surface tester (“WM-10,” product of TOPCON). The inspection was conducted while the film is disposed on a semiconductor wafer (diameter: 300 mm), and the number of particles having a size of 0.065 μm or more was counted. The number of particles corresponded to the number within an area of 70,685 mm². A number of 20 or smaller is evaluated as preferred, that of 15 or less being more preferred.

### (Film Thickness Distribution Measurement)

The film thickness of a molybdenum thin film on a wafer was measured at 49 points by means of “S-MAT2300” (product of TECHNORAYS). Film thickness distribution was calculated by the following formula:

$$Film thickness distribution ( \% ) = ( max . - min ) / ( max . + min . ) \times 100.$$

TABLE 1

| | Powder property | | | | | | | |
|---|---|---|---|---|---|---|---|---|
| | Morphological property of powder | | | | | | Sintering conditions | |
| | Average | | | | Metal | Gas | | HIP |
| | particle | D50 | D90/ | D95/ | W | O | HP temp. | conditions |
| | size (μm) | (μm) | av. size | av. size | (ppm) | (ppm) | (° C.) | (° C.) |
| Ex. 1 | 2.8 | 2.5 | 1.43 | 1.71 | 15 | 2,605 | 1,400 | 1,550 |
| Ex. 2 | 2.8 | 2.5 | 1.43 | 1.71 | 25 | 2,605 | 1,500 | 1,500 |
| Ex. 3 | 3.7 | 3.0 | 1.57 | 1.70 | 50 | 2,605 | 1,450 | 1,550 |
| Ex. 4 | 3.7 | 3.0 | 1.57 | 1.70 | 50 | 2,605 | 1,500 | 1,600 |
| Comp. Ex. 1 | 1.8 | 1.5 | 1.55 | 1.92 | 780 | 1,855 | 1,450 | — |
| Comp. Ex. 2 | 3.7 | 3.0 | 1.57 | 1.70 | 50 | 2,605 | 1,450 | — |
| Comp. Ex. 3 | 1.8 | 1.5 | 1.55 | 1.92 | 780 | 1,855 | 1,200 | 1,850 |
| Comp. Ex. 4 | 1.8 | 1.5 | 1.55 | 1.92 | 780 | 1,855 | 1,200 | 1,100 |
| Comp. Ex. 5 | 2.0 | 1.7 | 1.53 | 1.87 | 190 | 3,485 | 1,400 | 1,300 |
| Comp. Ex. 6 | 2.0 | 1.7 | 1.53 | 1.87 | 190 | 3,485 | 1,500 | 1,400 |
| Comp. Ex. 7 | 2.3 | 1.8 | 1.34 | 1.63 | 80 | 2,900 | 1,400 | 1,550 |
| Comp. Ex. 8 | 2.3 | 1.8 | 1.34 | 1.63 | 80 | 2,900 | 1,400 | 1,700 |
| Comp. Ex. 9 | 3.5 | 2.2 | 1.77 | 2.06 | 10 | 1,200 | 1,400 | 1,550 |
| Comp. Ex. 10 | 4.5 | 3.3 | 1.69 | 2.04 | 20 | 2,400 | 1,500 | 1,550 |
| Comp. Ex. 11 | 6.3 | 3.8 | 1.90 | 2.89 | 5 | 390 | 1,500 | 1,600 |
| Comp. Ex. 12 | 9.9 | 5.7 | 2.09 | 3.24 | 30 | 380 | 1,500 | 1,650 |
| Comp. Ex. 13 | 13.0 | 7.2 | 2.25 | 3.24 | 50 | 320 | 1,600 | 1,600 |

TABLE 2

| | | | | Crystal grain size | | | | | |
|---|---|---|---|---|---|---|---|---|---|
| | Relative | | | Average | 3σ/ | | Impurity content | | |
| | density | Vickers hardness | | grain size | average | Aspect | W content | C content | O content |
| | (%) | Av. (Hv) | 3σ/av. | (μm) | size | ratio | (mass ppm) | (mass ppm) | (mass ppm) |
| Ex. 1 | 99.5 | 173 | 0.06 | 65 | 0.9 | 1.0 | 15 | 20 | 19 |
| Ex. 2 | 99.4 | 176 | 0.05 | 48 | 1.0 | 1.1 | 22 | 16 | 23 |
| Ex. 3 | 99.7 | 170 | 0.06 | 83 | 1.0 | 1.1 | 50 | 27 | 24 |
| Ex. 4 | 99.7 | 169 | 0.06 | 72 | 1.2 | 1.0 | 55 | 26 | 22 |
| Comp. Ex. 1 | 99.1 | 181 | 0.16 | 22 | 1.2 | 1.1 | 740 | 19 | 508 |
| Comp. Ex. 2 | 94.7 | 172 | 0.06 | 10 | 1.1 | 1.1 | 44 | 12 | 21 |
| Comp. Ex. 3 | 99.9 | 179 | 0.06 | 800 | 1.4 | 1.4 | 520 | 20 | 1,100 |
| Comp. Ex. 4 | 96.5 | 244 | 0.07 | 12 | 1.1 | 1.1 | 550 | 20 | 675 |
| Comp. Ex. 5 | 98.0 | 183 | 0.13 | 23 | 1.2 | 1.0 | 188 | 14 | 788 |
| Comp. Ex. 6 | 98.7 | 183 | 0.13 | 24 | 1.1 | 1.1 | 179 | 14 | 620 |
| Comp. Ex. 7 | 99.8 | 177 | 0.07 | 42 | 0.8 | 1.0 | 80 | 14 | 75 |
| Comp. Ex. 8 | 99.8 | 176 | 0.07 | 600 | 1.5 | 1.6 | 80 | 14 | 80 |
| Comp. Ex. 9 | 98.8 | 171 | 0.09 | 53 | 1.3 | 1.2 | 10 | 20 | 10 |
| Comp. Ex. 10 | 98.7 | 172 | 0.10 | 42 | 1.4 | 1.2 | 20 | 20 | 20 |
| Comp. Ex. 11 | 98.2 | 170 | 0.13 | 86 | 1.5 | 1.5 | 5 | 16 | 20 |
| Comp. Ex. 12 | 97.9 | 178 | 0.13 | 450 | 1.8 | 1.4 | 30 | 21 | 17 |
| Comp. Ex. 13 | 97.3 | 175 | 0.16 | 55 | 1.6 | 1.3 | 50 | 60 | 20 |

TABLE 3

| | | | | | Film | |
|---|---|---|---|---|---|---|
| | Pores (number) | | | Specific | thickness | |
| | 0.1-0.2 | 0.2-1.8 | >1.8 | resistivity | distribution | Particles |
| | μm² | μm² | μm² | ≤11 μΩ · cm | ≤2% | ≥0.065 μm |
| Ex. 1 | 13 | 4 | 0.4 | O | O | 15 |
| Ex. 2 | 15 | 4 | 0.5 | O | O | 10 |
| Ex. 3 | 9 | 2 | 0.6 | O | O | 9 |
| Ex. 4 | 8 | 2 | 0.5 | O | O | 11 |
| Comp. Ex. 1 | 37 | 21 | 1.9 | X | X | 70 |
| Comp. Ex. 2 | 77 | 11 | 0.3 | O | O | 50 |
| Comp. Ex. 3 | 50 | 98 | 8.6 | X | X | 92 |
| Comp. Ex. 4 | 120 | 81 | 3.5 | X | O | 73 |
| Comp. Ex. 5 | 31 | 44 | 3.0 | X | O | 77 |
| Comp. Ex. 6 | 32 | 32 | 2.2 | X | O | 59 |
| Comp. Ex. 7 | 18 | 5 | 0.9 | X | O | 19 |
| Comp. Ex. 8 | 9 | 6 | 0.8 | X | X | 21 |
| Comp. Ex. 9 | 22 | 3 | 0.6 | O | O | 29 |
| Comp. Ex. 10 | 25 | 2 | 0.5 | O | O | 35 |
| Comp. Ex. 11 | 27 | 6 | 0.5 | O | X | 33 |
| Comp. Ex. 12 | 30 | 8 | 0.7 | O | X | 39 |
| Comp. Ex. 13 | 35 | 9 | 0.9 | X | X | 29 |

In Examples 1 to 4, there was used a powder having a tungsten content of 10 ppm to 100 ppm, molybdenum content (excluding tungsten and gas components) of 99.999 mass % or more (purity: 5N), an average particle size D_{Ave}, as determined through a laser diffraction/scattering method, of 2.5 to 4.0 μm, a median diameter D50 of 2.0 to 3.5, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less. The powder was hot-pressed at 1,400° C. to 1,500° C., and then subjected to HIP at 1,500° C. to 1,600° C., to thereby yield a molybdenum sintered body. The thus-obtained molybdenum sintered body can provide a molybdenum target which has a relative density of 99% or higher, and in which, in an observation field of 0.15 mm², 20 or fewer pores having a size of 0.01 μm² or greater and smaller than 0.2 μm² are present; 5 or fewer pores having a size of 0.2 μm² or greater and smaller than 1.8 μm² are present; and 1 or fewer pore having a size of 1.8 μm² or greater is present. By use of such a molybdenum target, generation of particles can be suppressed, and a high-quality molybdenum thin film can be consistently formed.

Also, in Examples 1 to 4, the temperature of hot-pressing was as low as 1,500° C. or lower. Thus, the carbon content of the target was sufficiently low, whereby a thin film having a sufficiently low specific resistivity of 11 μΩ·cm or lower was successfully formed.

In Comparative Example 1, the particle size of the powder was too small, and the oxygen content was high. As a result, the density of the sintered body steeply rose during HP, to thereby trap oxides. In Comparative Example 2, the density was insufficient, since no HIP was conducted.

In Comparative Examples 3 and 4, specific resistivity was high due to high tungsten content and oxygen content. In addition, since the particle size of the raw material powder was too small, the density of the sintered body steeply rose during HP. Furthermore, oxides remained without sublimation due to a low HP temperature. In Comparative Example 3, anomalous grain growth occurred due to high HIP temperature. In Comparative Example 4, the density of the sintered body was low due to low HIP temperature.

In Comparative Examples 5 and 6, specific resistivity was high due to high tungsten content and oxygen content. In addition, since the particle size of the raw material powder was too small, and the oxygen content was high, the density of the sintered body steeply rose during HP, to thereby trap oxides. The density of the sintered body was low due to low HIP temperature.

In Comparative Example 7, specific resistivity was high due to high oxygen content. Since the particle size of the raw material powder was too small, the density of the sintered body steeply rose during HP, and a part of oxides remained.

In Comparative Example 8, specific resistivity was high due to high oxygen content. Since the particle size of the raw material powder was too small, the density of the sintered body steeply rose during HP, and a part of oxides remained. Also, anomalous grain growth occurred due to high HIP temperature, resulting in a greater aspect ratio.

In Comparative Examples 9 to 11, the density of the sintered body was insufficient due to a large particle size of the raw material powder. In addition, in Comparative Example 11, control of the particle size of the power was unsatisfactory. Thus, variation in crystal grain size was observed, and a greater aspect ratio was provided. As a result, the density was insufficient.

In Comparative Example 12, anomalous grain growth occurred due to high HIP temperature, resulting in a greater aspect ratio. Also, the density of the sintered body was insufficient due to a large particle size of the raw material powder.

In Comparative Example 13, the amount of diffused carbon increased due to high HP temperature. Also, since control of the particle size distribution of the raw material power was unsatisfactory, variation in crystal grain size was observed, and a greater aspect ratio was provided. The density was insufficient due to a large particle size of the powder.

1. A molybdenum target formed of a sintered body of a molybdenum powder, wherein the molybdenum target comprises:
a relative density of 99% or higher,
an oxygen content of 25 ppm or less, a carbon content of 30 ppm or less,
a tungsten content of 10 ppm to 100 ppm, and
a molybdenum content, excluding the oxygen content, the carbon content, and the tungsten content, of 99.999 mass % or more; and
in an observation field of 0.15 mm², 20 or fewer pores having a size of 0.01 μm² or greater and smaller than 0.2 μm² are present; 5 or fewer pores having a size of 0.2 μm² or greater and smaller than 1.8 μm² are present; and 1 or fewer pore having a size of 1.8 μm² or greater is present.

2. The molybdenum target according to claim 1, wherein the molybdenum target further comprises:
an average grain size d_{Ave}, calculated as a circle-equivalent diameter, of 20 μm to 100 μm, and
a ratio (30/d_{Ave}) of a standard deviation 3σ of the grain sizes, calculated as circle-equivalent diameters, to the average grain size d_{Ave} of 1.2 or less.

3. The molybdenum target according to claim 2, wherein has an aspect ratio regarding grain size d less than 1.2.

4. The molybdenum target according to claim 1, further comprising:
an average Vickers hardness of 180 or less, and
a ratio (3σ/H_{Ave}) of a standard deviation 3σ of Vickers hardness values to a average Vickers hardness H_{Ave} of 0.07 or less.

5. A method for producing a molybdenum target, the method comprising:
using a molybdenum powder which has an average particle size D_{Ave} of 2.5 to 4.0 μm, the particle size being determined through a laser diffraction/scattering method, a median diameter D50 of 2.0 to 3.5, a ratio (D90/D_{Ave}) of a median diameter D90 to the average particle size D_{Ave} of 1.7 or less, and a ratio (D95/D_{Ave}) of a median diameter D95 to the average particle size D_{Ave} of 2.0 or less;
hot-pressing the molybdenum powder at 1,400° C. to 1,500° C.; and
subsequently, sintering a hot-pressed product at 1,500° C. to 1,600° C. through a hot isostatic pressing method.

6. The method for producing the molybdenum target according to claim 5, wherein
the molybdenum powder has a tungsten content of 10 ppm to 100 ppm, and
a molybdenum content, excluding an oxygen content, a carbon content, and the tungsten content, of 99.999 mass % or more.

7. The method for producing the molybdenum target according to claim 5, wherein the hot-pressing is conducted in high vacuum at a retention temperature of 1,400 to 1,500° C. for a retention time of 360 to 600 minutes.
